(19) United States
(12) Patent Application Publication
(10) Pub. No.: US 2004/0253823 A1
(43) Pub. Date: Dec. 16, 2004

(54) Dielectric plasma etch with deep uv resist and power modulation

(75) Inventors: Hun-Jan Taq, Hsinchu (TW); Hsien-Kuang Chiu, Hsinchu (TW); Fang-Cheng Chen, Hsin-Chu (TW)

Correspondence Address: GEORGE O. SAILE, 28 DAVIS AVENUE, POUGHKEEPSIE, NY, 12603, US

(73) Assignee: Taiwan Semiconductor Manufacturing Co.

(21) Appl. No.: 10/889,749

(22) Filed: Jul. 13, 2004

Related U.S. Application Data
(63) Continuation-in-part of application No. 09/953,523, filed on Sep. 17, 2001.

(51) Int. Cl. H01L 21/302; H01L 21/461

(52) U.S. Cl. 438/691

(57) ABSTRACT

A method of etching a dielectric layer comprising the following steps. A structure having the dielectric layer formed thereover is provided. A patterned photoresist layer that may be a non-aromatic positive patterned photoresist layer is formed over the dielectric layer. The patterned photoresist layer is used as a mask while etching the dielectric layer with an etching gas comprising a fluorocarbon, and may also further comprise O₂, while modulating one or both select powers on and off with a duty cycle or wave form. The select powers being selected from the group consisting of an RF power and a bias power.

This Patent Application is a Continuation-in-Part of attorney docket number TSMC 01-189, filed as U.S. patent application Ser. No. 09/953523, filed on Sep. 17, 2001, which is hereby incorporated by reference in its entirety.

### FIELD OF THE INVENTION

The present invention relates generally to semiconductor fabrication and more specifically to dielectric etching processes using patterned photoresist masks.

### BACKGROUND OF THE INVENTION

As shown in FIG. 1, ArF light (wavelength 193 nm) or F2 laser (wavelength 157 nm) patterned photoresist (resist) 120 formed over structure 100 is susceptible to being damaged by plasma etching resulting in resist tilting during etching of polysilicon or metal layers.

Such profile tilting is strongly correlated to the electron-temperature and ion flux and does not permit a good profile or critical dimension (CD) control. It is very difficult to totally resolve this problem by traditional plasma etching because it is difficult to independently control the total flux, electron temperature and other process trends. The resist has a non-aromatic structure, i.e. without phenyl rings in the structure.

This tilting shown in FIG. 1 is believed to be caused by a synergistic effect from: (i) low mechanical strength of deep ultraviolet (DUV) resist under directional plasma etching; (ii) enhanced sidewall bombardment by ion due to the resist charging; and (iii) electrostatic distortion due to the resist charging.

Based upon this proposed mechanism of tilting, several approaches to improve the etching condition have been proposed: (i) reduce power or use reactive ion etch (RIE) etcher to reduce the electron temperature; (ii) lower the wafer temperature; (iii) add a hydrogen containing source to neutralize the surface negative charging on the resist; and (iv) increase the bias power to minimize the ion deviation and residence time in the plasma. Even though these approaches can improve DUV resist tilting, the tilting has yet to be totally resolved due to the intrinsic limitation of the inherent high electron temperature.

U.S. Pat. No. 6,136,723 to Nagase describes a method of fabricating a semiconductor device using a KrF deep ultraviolet (DUV) resist and a fluorocarbon etch.

U.S. Pat. No. 5,770,097 to O'Neill et al. describes a method of controlling etch selectivity.

U.S. Pat. No. 5,705,443 to Stauf et al. describes a plasma-assisted dry etching process for etching of a metal containing material layer on a substrate to remove the metal containing material from the substrate.

U.S. Pat. No. 5,614,060 to Hanawa describes a process and apparatus for patterning a masked metal layer to form a layer of metal interconnects for an integrated circuits structure which removes metal etch residues while inhibiting or eliminating erosion of the photoresist mask.

The Journal of Vacuum Science & Technology B article entitled “Pulse-Time-Modulated ICP Etching” by Ohtake et al., Vol. 18, No. 5 (2000), pages 2495 to 2499, discloses a inductively coupled plasma (ICP) etching system and method of patterning photoresist using KrF eximer light.

### SUMMARY OF THE INVENTION

Accordingly, it is an object of an embodiment of the present invention to provide an improved method of etching dielectric layers while using patterned photoresist masks.

Other objects will appear hereinafter.

It has now been discovered that the above and other objects of the present invention may be accomplished in the following manner. Specifically, a structure having the dielectric layer formed thereover is provided. A patterned photoresist layer that may be a non-aromatic positive patterned photoresist layer is formed over the dielectric layer. The patterned photoresist layer is used as a mask while etching the dielectric layer with an etching gas comprising a fluorocarbon, and may also further comprise O₂, while modulating one or both select powers on and off with a duty cycle or wave form. The select powers being selected from the group consisting of an RF power and a bias power.

### BRIEF DESCRIPTION OF THE DRAWINGS

The present invention will be more clearly understood from the following description taken in conjunction with the accompanying drawings in which like reference numerals designate similar or corresponding elements, regions and portions and in which:

FIG. 1 schematically illustrates photoresist tilting after prior art plasma etching.

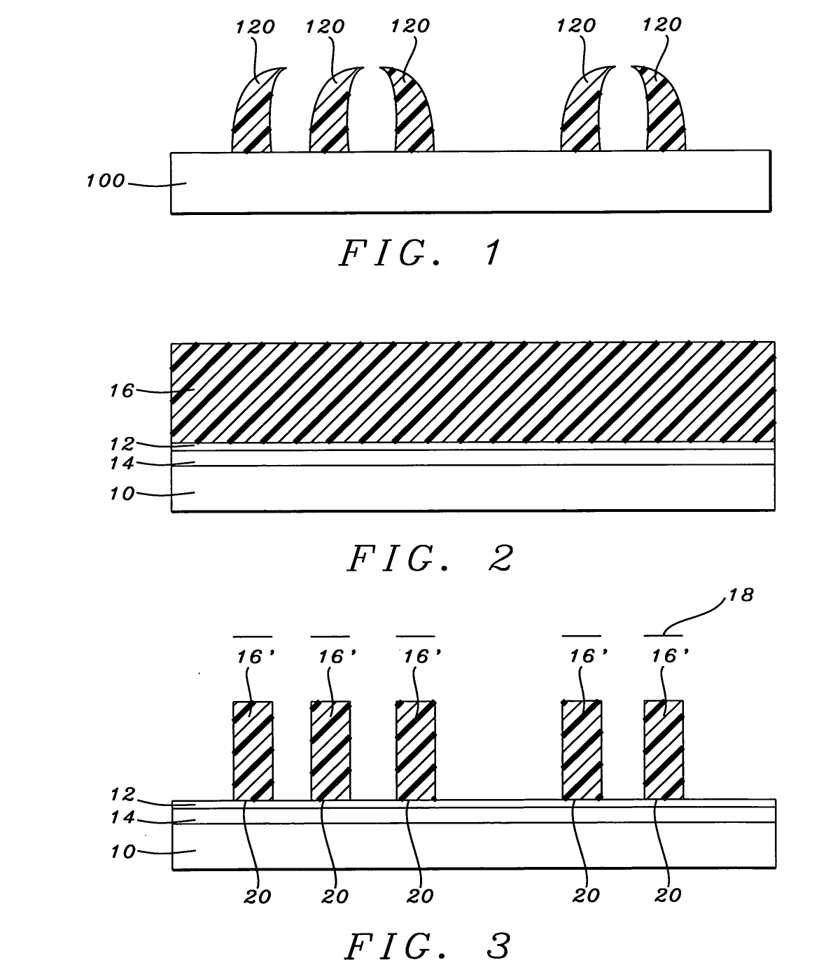

FIGS. 2 to 4 schematically illustrate a preferred embodiment of the present invention.

### DETAILED DESCRIPTION OF THE PREFERRED EMBODIMENT

### Brief Summary of the Invention

In a key feature of the present invention, using an etching gas including/comprising a fluorocarbon, and which may also include/comprise O₂, pulse modulation is used to reduce the electron temperature without substantially affecting the etching conditions and performance while etching dielectric layers using a DUV mask. The input RF signal and/or the bias is modulated on (plasma-on state) and off (plasma-off state) with a duty cycle so that the electron temperature is reduced during the plasma-off state. Another key factor is that a hydrogen (H) atom as a plasma species containing source enhances the method of the present invention.

### Initial Structure

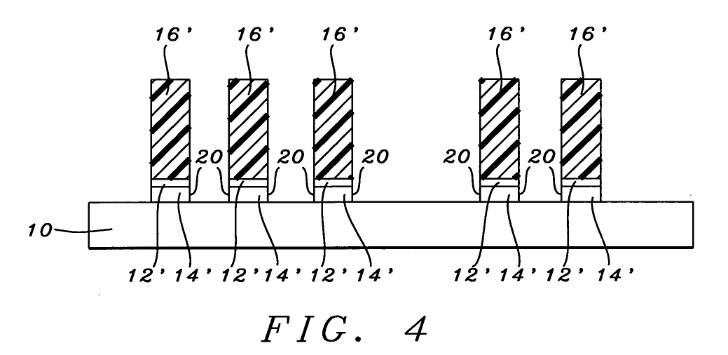

Accordingly as shown in FIG. 2, structure 10 is understood to possibly include a semiconductor wafer or substrate, active and passive devices formed within the wafer, conductive layers and dielectric layers (e.g., inter-poly oxide (IPO), intermetal dielectric (IMD), etc.) formed over the wafer surface. The term “semiconductor structure” is meant to include devices formed within a semiconductor wafer and the layers overlying the wafer.

Dielectric layer 14 is formed over structure 10 to a thickness of preferably from about 500 to 10,000 Å and more preferably from about 1000 to 6000 Å. Dielectric layer 14 may be a single layer or multi-layer and is preferably comprised of a low-k material such as nitride, oxide or oxynitride, silicon nitride (SiN), silicon oxide, silicon oxynitride (SiON), oxide/SiN or SiON/oxide for example.

Optionally, anti-reflective coating (ARC) layer 12 may be formed over dielectric layer 14. ARC layer 12 has a thickness of preferably from about 200 to 2000 Å, more preferably from about 300 to 1500 Å and most preferably from about 300 to 900 Å. ARC layer 12 is preferably formed of an organic material, oxynitride, nitride or TiN and is more preferably formed of an organic material or oxynitride.

Photoresist layer 16 is formed over ARC layer 12/dielectric layer 14 to a thickness of preferably from about 0.05 to 0.80 μm and more preferably from about 0.10 to 0.40 μm. Photoresist layer 16 is preferably either a positive non-aromatic photoresist or a negative non-aromatic photoresist. Positive, non-aromatic photoresist layer 16 is preferably comprised of ether, ester, acrylic, fluorocarbon or having a cyclic aliphatic structure. Negative, non-aromatic photoresist layer 16 is preferably comprised of acrylate polymer, cyclic olefin polymer, fluoro polymer, silicon polymer or cyano polymer and is more preferably acrylate polymer or cyclic olefin polymer.

### Patterning of Photoresist Layer 16

As shown in FIG. 3, negative or positive (non-aromatic) photoresist layer 16 is exposed and patterned using a DUV mask 18 for negative photoresist layer 16 (and, as one skilled in the art would recognize, a DUV mask (not shown) complimentary to DUV mask 18 would be used to expose positive photoresist layer 16) with either ArF eximer light (wavelength 193 nm) or F2 eximer light (wavelength 157 nm) to form patterned photoresist layer 16′. Patterned photoresist layer 16′ overlies portions 20 of ARC layer 12/dielectric layer 14. Other wavelengths of light, or other patterning sources, may also be used such as UV light, e-beam or x-ray (the resist is also acrylate system).

### Key Step of the Invention

In a key step of the invention and as shown in FIG. 4, using an etching gas including: (1) a fluorocarbon; or (2) a fluorocarbon and O₂; to etch ARC layer 12/dielectric layer 14 using patterned photoresist layer 16′ masking portions 20 of ARC layer 12/dielectric layer 14 to form patterned ARC layer 12′/dielectric layer 14′, the input RF signal (RF power) and/or the bias power is/are modulated on (plasma-on state) and off (plasma-off state) with various duty cycles or wave forms to reduce the electron temperature during the plasma-off state without a significant change to the etching conditions. For example, a 30% ON duty cycle may be used. Both the RF signal and the bias are independently controlled.

An optional additional hydrogen atom as a plasma species containing source gas further enhances the method of the present invention.

The source RF power is preferably from about 10 to 60 MHz and the bias applied to the structure 10 is preferably from about 2 to 20 MHz.

The fluorocarbon and O₂ containing etching gas preferably includes/comprises:

(I) (a) O₂ supplied at preferably from about 0 to 70 sccm, more preferably from about 1 to 70 sccm and most preferably from about 10 to 30 sccm; and (b) C₄F₈, C₅F₈, C₄F₆, C₂F₆, CF₄, C₃F₈ or C₂F₄ supplied at preferably from about 10 to 100 sccm and more preferably from about 20 to 40 sccm; and more preferably includes/comprises:

II) (a) O₂ supplied at preferably from about 0 to 70 sccm, more preferably from about 1 to 70 sccm and most preferably from about 10 to 30 sccm.; and C₂F₆, CF₄ or C₄F₈ supplied at preferably from about 10 to 100 sccm and more preferably from about 20 to 40 sccm.

The fluorocarbon containing etching gas preferably includes/comprises C₄F₈, C₅F₈, C₄F₆, C₂F₆, CF₄, C₃F₈ or C₂F₄, more preferably includes/comprises C₂F₆, CF₄ or C₄F₈ and is supplied at preferably from about 5 to 100 sccm and more preferably from about 10 to 40 sccm.

The optional hydrogen containing gas preferably is comprised of HBr, CHF₃, H₂, CH₂F₂, or CH₃F and is more preferably is comprised of CH₂F₂ and is supplied at preferably from about 5 to 50 sccm and more preferably from about 10 to 40 sccm.

The etching of ARC layer 12/dielectric layer 14 is preferably carried out in a dielectric etcher or a poly etcher with inductive type high-density plasma (inductively coupled plasma (ICP)) or a capacitive-type low-density/medium density plasma and is more preferably carrier out in an ICP etcher.

The input RF and/or bias waveform and power are adjusted until the DUV resist is not tilted by the fluorocarbon containing etching gas in accordance with the method of the present invention.

Further processing may then proceed.

### Advantages of the Present Invention

The advantages of one or more embodiments of the present invention include avoiding the DUV resist tilting simply by adjusting the RF/bias power modulation cycle without dramatically changing the etching chemistry.

While particular embodiments of the present invention have been illustrated and described, it is not intended to limit the invention, except as defined by the following claims.

We claim:

1. A method of etching a dielectric layer, comprising the steps of:
providing a structure having the dielectric layer formed thereover;
forming a non-aromatic positive patterned photoresist layer over the dielectric layer; and
using the non-aromatic positive patterned photoresist layer as a mask, etching the dielectric layer with an etching gas comprising a fluorocarbon while modulating one or both select powers on and off with a duty cycle or wave form; the select powers selected from the group consisting of: an RF power and a bias power.

2. The method of claim 1, wherein an ARC layer is formed over the dielectric layer.

3. The method of claim 1, wherein an ARC layer is formed over the dielectric layer; the ARC layer is an organic material, oxynitride, nitride or TiN; the ARC layer having a thickness of from about 200 to 2000 Å.

4. The method of claim 1, wherein the structure is a semiconductor structure; the dielectric layer is a low-k material, nitride, oxide, oxynitride, SiN, silicon oxide, SiON, oxide/SiN or SiON/oxide; and the non-aromatic positive patterned photoresist layer is ether, ester, acrylic, fluorocarbon or having a cyclic aliphatic structure.

5. The method of claim 1, wherein the dielectric layer has a thickness of from about 500 to 10,000 Å and the non-aromatic positive patterned photoresist has a thickness of from about 0.05 to 0.80 μm.

6. The method of claim 1, wherein the etching gas comprising a fluorocarbon comprises a C₄F₈, C₅F₈, C₄F₆, C₂F₆, CF₄, C₃F₈ or C₂F₄ fluorocarbon.

7. The method of claim 1, wherein the etching gas comprising a fluorocarbon further comprises: O₂; and a C₄F₈, C₅F₈, C₄F₆, C₂F₆, CF₄, C₃F₈ or C₂F₄ fluorocarbon.

8. The method of claim 1, wherein the etching gas comprising a fluorocarbon has a flow rate of from about 5 to 100 sccm.

9. The method of claim 1, wherein the etching gas comprising a fluorocarbon further comprises O₂; and has an O₂ flow rate of from about 1 to 70 sccm and a fluorocarbon flow rate of from about 10 to 100 sccm.

10. The method of claim 1, wherein the etching gas comprising a fluorocarbon further comprises O₂; and has an O₂ flow rate of from about 10 to 30 sccm and has a fluorocarbon flow rate of from about 20 to 40 sccm.

11. The method of claim 1, wherein the dielectric layer etching step comprises a hydrogen atom as a plasma species containing gas.

12. The method of claim 1, wherein the dielectric layer etching step comprises a hydrogen atom as a plasma species containing gas, the hydrogen atom as a plasma species containing gas having a flow rate of from about 5 to 50 sccm.

13. The method of claim 1, wherein the dielectric layer etching step comprises a hydrogen atom as a plasma species containing gas comprised of HBr, CHF₃, H₂, CH₂F₂ or CH₃F.

14. The method of claim 1, wherein the select powers comprise both the RF power and the bias power with the modulation of the RF power and the bias power being independently controlled; the RF power being from about 10 to 60 MHz; and the bias power being from about 2 to 20 MHz.

15. The method of claim 1, wherein the dielectric layer etching step does not cause tilting of the non-aromatic positive patterned photoresist layer.

16. A method of etching a dielectric layer, comprising the steps of:
providing a structure having the dielectric layer formed thereover;
forming a non-aromatic patterned non-aromatic photoresist layer over the dielectric layer; and
using the patterned non-aromatic photoresist layer as a mask, etching the dielectric layer with an etching gas comprising a fluorocarbon and O₂ while modulating one or both select powers on and off with a duty cycle or wave form; the select powers selected from the group consisting of: an RF power and a bias power.

17. The method of claim 16, wherein an ARC layer is formed over the dielectric layer.

18. The method of claim 16, wherein an ARC layer is formed over the dielectric layer; the ARC layer is an organic material, oxynitride, nitride or TiN; the ARC layer having a thickness of from about 200 to 2000 Å.

19. The method of claim 16, wherein the structure is a semiconductor structure; the dielectric layer is a low-k material, nitride, oxide, oxynitride, SiN, silicon oxide, SiON, oxide/SiN or SiON/oxide; and the patterned non-aromatic photoresist layer is:
a non-aromatic negative photoresist material comprised of acrylate polymer, cyclic olefin polymer, fluoro polymer, silicon polymer or cyano polymer; or
a non-aromatic positive photoresist material comprised of ether, ester, acrylic, fluorocarbon or a cyclic aliphatic structure.

20. The method of claim 16, wherein the structure is a semiconductor structure; the dielectric layer is a low-k material, nitride, oxide, oxynitride, SiN, silicon oxide, SiON, oxide/SiN or SiON/oxide; and the patterned photoresist layer is a:
non-aromatic negative photoresist material comprised of acrylate polymer or cyclic olefin polymer; or
a non-aromatic positive photoresist material comprised of ether, ester, acrylic, fluorocarbon or a cyclic aliphatic structure.

21. The method of claim 16, wherein the dielectric layer has a thickness of from about 500 to 10,000 Å and the patterned non-aromatic photoresist has a thickness of from about 0.05 to 0.80 μm.

22. The method of claim 16, wherein the etching gas comprising a fluorocarbon and O₂ comprises O₂ and a fluorocarbon comprised of C₄F₈, C₅F₈, C₄F₆, C₂F₆, CF₄, C₃F₈ or C₂F₄.

23. The method of claim 16, wherein the etching gas comprising a fluorocarbon and O2 comprises O₂ and a fluorocarbon comprised of C₂F₆, CF₄ or C₄F₈.

24. The method of claim 16, wherein the etching gas comprising a fluorocarbon and O₂ has a fluorocarbon flow rate of from about 5 to 100 sccm.

25. The method of claim 16, wherein the etching gas comprising a fluorocarbon and O₂ has a fluorocarbon flow rate of from about 10 to 100 sccm, and an O₂ flow rate of from about 1 to 70 sccm.

26. The method of claim 16, wherein the etching gas comprising a fluorocarbon and O₂ has a fluorocarbon flow rate of from about 20 to 40 sccm, and an O₂ flow rate of from about 10 to 30 sccm.

27. The method of claim 16, wherein the dielectric layer etching step comprises a hydrogen atom as a plasma species containing gas; the RF power being from about 10 to 60 MHz; and the bias power being from about 2 to 20 MHz.

28. The method of claim 16, wherein the dielectric layer etching step comprises a hydrogen atom as a plasma species containing gas and has a flow rate of from about 5 to 50 sccm.

29. The method of claim 16, wherein the dielectric layer etching step comprises a hydrogen atom as a plasma species containing gas is HBr, CHF₃, H₂, CH₂F₂ or CH₃F.

30. The method of claim 16, wherein the select powers comprise both the RF power and the bias power with the modulation of the RF power and the bias power being independently controlled.

31. The method of claim 16, wherein the dielectric layer etching step does not cause tilting of the patterned non-aromatic photoresist layer.

32. A method of etching a dielectric layer, comprising the steps of:
providing a structure having the dielectric layer formed thereover;
forming an ARC layer over the dielectric layer;
forming a non-aromatic positive patterned non-aromatic photoresist layer over the dielectric layer; and
using the patterned non-aromatic positive photoresist layer as a mask, etching the ARC layer and the dielectric layer with an etching gas comprising a fluorocarbon and O₂ while modulating one or both select powers on and off with a duty cycle or wave form; the select powers being an RF power or a bias power; the dielectric layer etching step comprising a hydrogen atom as a plasma species containing gas; the RF power being from about 10 to 60 MHz; and the bias power being from about 2 to 20 MHz.

33. The method of claim 32, wherein the ARC layer is an organic material, oxynitride, nitride or TiN; the ARC layer having a thickness of from about 200 to 2000 Å.

34. The method of claim 32, wherein the structure is a semiconductor structure; the dielectric layer is a low-k material, nitride, oxide, oxynitride, SiN, silicon oxide, SiON, oxide/SiN or SiON/oxide; the ARC layer is an organic material, oxynitride, nitride or TiN; and the patterned non-aromatic positive photoresist layer is a ether, ester, acrylic, fluorocarbon or a cyclic aliphatic structure.

35. The method of claim 32, wherein the dielectric layer has a thickness of from about 500 to 10,000 Å; the ARC layer has a thickness of from about 200 to 2000 Å; and the patterned non-aromatic positive photoresist has a thickness of from about 0.05 to 0.80 μm.

36. The method of claim 32, wherein the etching gas comprising a fluorocarbon and O₂ comprises O₂ and a C₄F₈, C₅F₈, C₄F₆, C₂F₆, CF₄, C₃F₈ or C₂F₄ fluorocarbon.

37. The method of claim 32, wherein the etching gas comprising a fluorocarbon and O₂ has a fluorocarbon flow rate of from about 10 to 100 sccm and an O₂ flow rate of from about 1 to 70 sccm.

38. The method of claim 32, wherein the etching gas comprising a fluorocarbon and O₂ has a fluorocarbon flow rate of from about 20 to 40 sccm and an O₂ flow rate of from about 10 to 30 sccm.

39. The method of claim 32, wherein the hydrogen atom as a plasma species containing gas having a flow rate of from about 5 to 50 sccm.

40. The method of claim 32, wherein the hydrogen atom as a plasma species containing gas is HBr, CHF₃, H₂, CH₂F₂ or CH₃F.

41. The method of claim 32, wherein the select power comprises both the RF power and the bias power with the modulation of the RF power and the bias power being independently controlled.

42. The method of claim 32, wherein the dielectric layer etching step does not cause tilting of the patterned non-aromatic positive photoresist layer.
